(19) United States
(12) Patent Application Publication
(10) Pub. No.: US 2026/0363019 A1
(43) Pub. Date: Nov. 12, 2026

(54) TRANSFER MACHINE

(71) Applicant: Daifuku Co., Ltd., Osaka-shi (JP)

(72) Inventor: Kazuya OMORI, Shiga (JP)

(73) Assignee: Daifuku Co., Ltd., Osaka-shi (JP)

(21) Appl. No.: 19/640,487

(22) Filed: Apr. 7, 2026

(30) Foreign Application Priority Data
May 9, 2025 (JP) 2025-078935

(51) Int. Cl. H10P 72/30; B08B 15/02; B65G 47/90

(52) U.S. Cl. CPC H10P 72/3206; B08B 15/02; B65G 47/901; B65G 2201/0297; B65G 2207/26

(57) ABSTRACT

A transfer machine includes: a base having a wall intersecting an up-down direction; a transfer unit movably provided on the base, the transfer unit being configured to support and transfer an article; a drive unit provided on the base and having an output unit; a power transmission mechanism provided on the base and having a plurality of operating parts, the power transmission mechanism being configured to transmit an operation of the output unit to the transfer unit to operate the transfer unit; and a cover provided on the base and covering a portion of the power transmission mechanism that generates dust by the operation of the operating parts between the cover and the wall, wherein an opening penetrating the wall in the up-down direction is formed in a portion of the wall covered by the cover.

### CROSS-REFERENCE TO RELATED APPLICATION(S)

The present application claims priority to and incorporates by reference the entire contents of Japanese Patent Application No. 2025-078935 filed in Japan on May 9, 2025.

### BACKGROUND

### 1. Field

The present disclosure relates to a transfer machine.

### 2. Description of the Related Art

In the related art, there is known a transfer machine having an extendable fork as a transfer mechanism (see, for example, JP H07-101503 A). In JP H07-101503 A, a cover covers a part of an actuator unit that converts rotation of a motor into extension and contraction of the fork, thereby preventing the dust generated in the cover from leaking to the outside of the cover.

In the structure of JP H07-101503 A, although leakage of dust to the outside of the cover can be suppressed, the dust is accumulated in the cover. In this case, for example, there is a possibility that inconvenience may occur such as an increase in resistance due to the dust when an operating part of the actuator in the cover is operated, or that a trouble or time is required for removing the dust accumulated in the maintenance performed with the cover removed.

There is a need for a transfer machine that can suppress accumulation of dust in a cover, for example, in a transfer machine including the cover that covers a portion where dust may be generated.

### SUMMARY

In some embodiments, a transfer machine includes: a base having a wall intersecting an up-down direction; a transfer unit movably provided on the base, the transfer unit being configured to support and transfer an article; a drive unit provided on the base and having an output unit; a power transmission mechanism provided on the base and having a plurality of operating parts, the power transmission mechanism being configured to transmit an operation of the output unit to the transfer unit to operate the transfer unit; and a cover provided on the base and covering a portion of the power transmission mechanism that generates dust by the operation of the operating parts between the cover and the wall, wherein an opening penetrating the wall in the up-down direction is formed in a portion of the wall covered by the cover.

The above and other objects, features, advantages and technical and industrial significance of this disclosure will be better understood by reading the following detailed description of presently preferred embodiments of the disclosure, when considered in connection with the accompanying drawings.

### BRIEF DESCRIPTION OF THE DRAWINGS

FIG. 1 is an exemplary schematic side view of a conveyance device including a transfer machine according to an embodiment and a storage shelf;

FIG. 2 is an exemplary schematic perspective view of the transfer machine according to the embodiment;

FIG. 3 is an exemplary schematic perspective view of a part of the transfer machine according to the embodiment;

FIG. 4 is an exemplary schematic perspective view of the part of the transfer machine illustrated in FIG. 3 with a cover removed;

FIG. 5 is an exemplary schematic perspective view of the part of the transfer machine illustrated in FIG. 3 with the cover removed in a state where a bracket of a motor is removed for convenience;

FIG. 6 is an exemplary schematic plan view of a part of the transfer machine according to the embodiment;

FIG. 7 is an exemplary schematic perspective view of a transfer machine of an embodiment including a modification of an opening formed in a wall in the same state as that of FIG. 4; and

FIG. 8 is an exemplary schematic side view of a conveyance device according to an embodiment, including a modification of an air conditioner and a storage shelf.

### DETAILED DESCRIPTION OF THE PREFERRED EMBODIMENTS

Hereinafter, exemplary embodiments and modifications of the present disclosure are disclosed. The structures of the embodiments and modifications described below and actions and results (effects) obtained from the structures are exemplary. The present disclosure can also be implemented by structures other than those disclosed in the following embodiments and modifications. In addition, according to the present disclosure, it is possible to obtain at least one of various effects (including derivative effects) obtained by the following structures. In addition, the embodiments and the modifications include similar components. In the drawings, similar components are denoted by the same reference numerals, and redundant description will be omitted.

In the present specification, ordinal numbers can be given for the convenience of distinguishing directions, parts, positions, portions, mechanisms, members, and the like. Note that an ordinal number does not necessarily indicate the priority or order, nor does it necessarily specify the number of items.

In each drawing, arrows indicating directions are illustrated. The X direction, the Y direction, and the Z direction intersect each other and are substantially orthogonal to each other. The Z direction substantially coincides with a vertically upward direction and may also be referred to as an upward direction, and a direction opposite to the Z direction may also be referred to as a downward direction. The X direction and the Y direction intersect the up-down direction and substantially coincide with a horizontal direction. The X direction and the Y direction may also be referred to as lateral directions.

### Conveyance Device and Storage Shelf

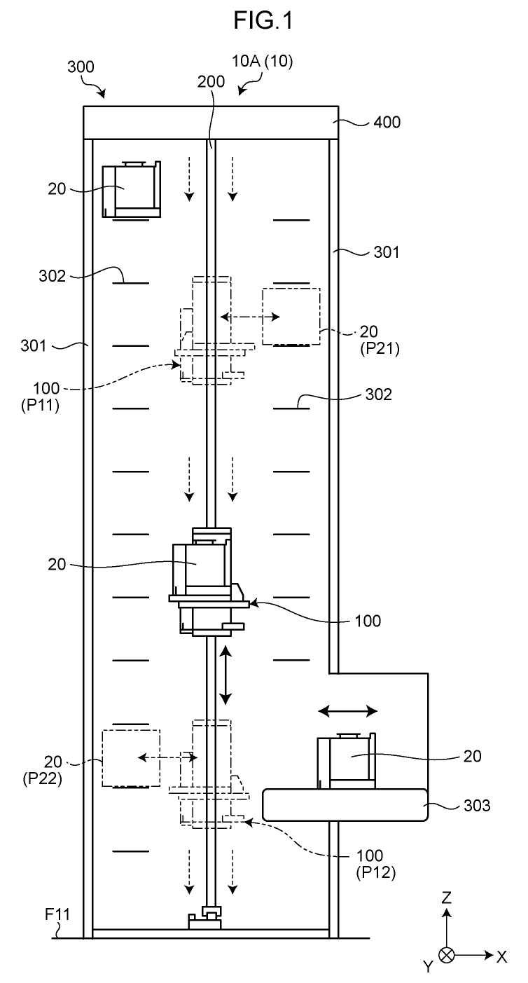

FIG. 1 is a side view of a conveyance device 10A (10) and a storage shelf 300. The conveyance device 10 includes a mast 200 extending in the up-down direction and a transfer machine 100 supported by the mast 200 in such a manner as to be movable in the up-down direction. The transfer machine 100 is capable of stopping at a plurality of positions in the Z direction. The transfer machine 100 can move while supporting a storage container 20 that accommodates an article. The article accommodated in the storage container 20 is, for example, a semiconductor wafer, a circuit board, an electronic component, or the like, but is not limited thereto. The storage container 20 can also be referred to as a conveyance object. In addition, the storage container 20 itself may also be referred to as an article.

In addition, a travelling carriage (not illustrated) capable of transporting the mast 200 in the Y direction and the direction opposite to the Y direction is provided below the mast 200. The travelling carriage is capable of stopping at a plurality of positions in the Y direction.

The storage shelf 300 is installed in such a manner as to be adjacent to the conveyance device 10 in the X direction and the direction opposite to the X direction. The storage shelf 300 includes support columns 301 each extending in the Z direction and a plurality of shelf members 302 fixed to the support columns 301. The shelf members 302 are provided at predetermined intervals in the Z direction and each can support a storage container 20. The space above a shelf member 302 accommodates a storage container 20. The spaces for accommodating storage containers 20 are arranged in a matrix shape when viewed in the X direction.

A blower 400 that generates a downflow of air (airflow in a direction opposite to the Z direction) is provided at an upper part of the storage shelf 300. The blower 400 is, for example, a fan filter unit (FFU). The airflow delivered from the blower 400 and flowing downward hits the transfer machine 100. In the present embodiment, the conveyance device 10 and the storage shelf 300 are installed on a floor F11.

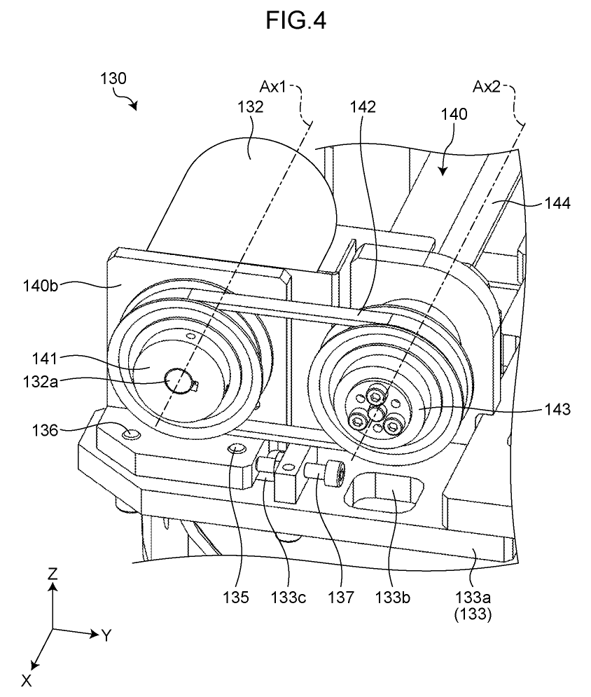

In this structure, the transfer machine 100 can be positioned at a position adjacent to each of storage positions of the shelf members 302 (for example, P21 and P22 in FIG. 1) in the X direction or in the opposite direction of the X direction (for example, P11 and P12 in FIG. 1). The transfer machine 100 includes a transfer mechanism 130 ( see FIG. 4 and others to be described later) capable of delivering and receiving a storage container 20 to and from a shelf member 302. The transfer machine 100 can be positioned at a position (P11 or P12) facing a storage position (P21 or P22, respectively) and deliver a storage container 20 into the storage position (P21 or P22) or carry the storage container 20 out of the storage position (P21 or P22, respectively) using the transfer mechanism 130.

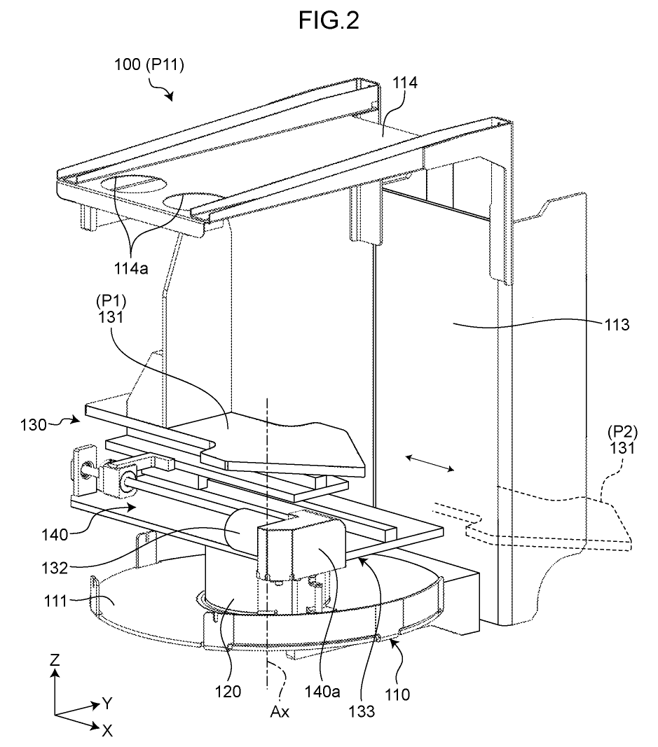

FIG. 2 is a perspective view of the transfer machine 100. In FIG. 2, the transfer machine 100 is positioned at the position P11 (see FIG. 1) and in an attitude in which the storage container 20 can be delivered to or received from the storage position P21 of the shelf member 302 adjacent to the transfer machine 100 in the X direction.

As illustrated in FIG. 2, the transfer machine 100 includes a first base 110, a pivoting unit 120, and the transfer mechanism 130.

The first base 110 is movably supported by the mast 200 (see FIG. 1) via a moving mechanism (not illustrated) including rollers and the like. The first base 110 includes a bottom plate 111, a side plate 113, a top plate 114, and others. The bottom plate 111 intersects with and is substantially orthogonal to the Z direction. The side plate 113 and the top plate 114 have functions of protecting a side part and an upper part of a storage container 20 held by the transfer mechanism 130 of the transfer machine 100 and supporting the moving mechanism, electric components such as a sensor, and others.

The pivoting unit 120 is supported by the first base 110 in such a manner as to be pivotable about the pivot axis Ax. The pivoting unit 120 can pivot about the pivot axis Ax by operation of an electric motor (not illustrated) or the like provided to the first base 110. The transfer mechanism 130 is attached to the pivoting unit 120. With the pivoting unit 120 pivoting, the transfer mechanism 130 can pivot relatively with respect to the first base 110 between the attitude illustrated in FIG. 2 and an attitude rotated by 180° (that is, reversed) about the pivot axis Ax from the attitude illustrated in FIG. 2 (not illustrated).

### Transfer Mechanism

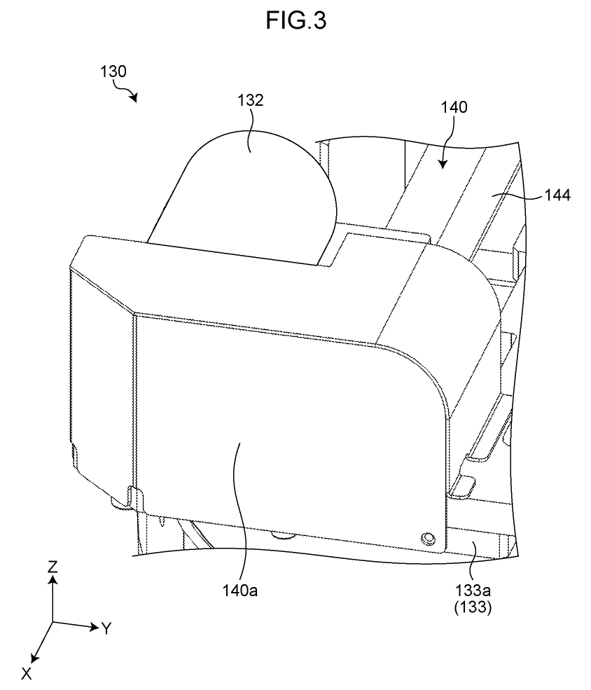

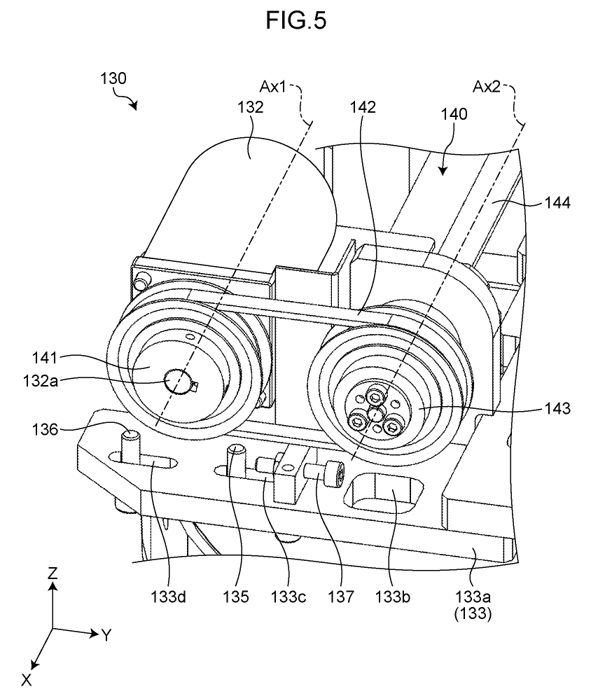

FIG. 3 is a perspective view of a part of the transfer mechanism 130. FIG. 4 is a perspective view of a state in which a cover 140a is removed from FIG. 3. Furthermore, FIG. 5 is a perspective view illustrating a state in which only a bracket 140b is removed from the state of FIG. 4 for convenience.

As illustrated in FIG. 3 to 5, the transfer mechanism 130 includes a transfer unit 131 (see FIG. 2), a motor 132, a second base 133, and a power transmission mechanism 140. The second base 133 is an example of a base constituting a part of the transfer mechanism 130 (pivoting unit 120).

The transfer unit 131 moves between a retracting position P1 and a protruding position P2 in FIG. 2 in a state of supporting the storage container 20, whereby the storage container 20 can be transferred to and from positions outside the transfer machine 100 such as the storage positions P21 and P22. Note that the transfer unit is not limited to a structure of linear motions as in the present embodiment, and may have another structure such as swinging. The transfer unit 131 may also be referred to as a support unit.

The motor 132 is, for example, an electric motor. The motor 132 has a shaft 132aas an output unit. The motor 132 is provided to the second base 133. The motor 132 is an example of a drive unit. In the present embodiment, the motor 132 may also be referred to as a rotation drive unit, and the shaft 132a may also be referred to as a rotation unit.

The transfer unit 131, the motor 132, and the power transmission mechanism 140 are all provided to the second base 133. Specifically, the transfer unit 131 is provided movably with respect to the second base 133. Fixing units of the motor 132 and the power transmission mechanism 140 are each fixed to the second base 133. Movable portions of the motor 132 and the power transmission mechanism 140 are each provided in such a manner as to be movable relative to the second base 133. In addition, the second base 133 has a wall 133aintersecting the up-down direction.

As illustrated in FIG. 4, the power transmission mechanism 140 includes pulleys 141 and 143, a belt 142, and a shaft 144. The pulley 141 is fixed to the shaft 132aand pivots about the pivot axis Ax1 together with the shaft 132a. The belt 142 is an endless belt, is wound around the pulleys 141 and 143, and transmits the pivoting of the pulley 141 to the pulley 143. The pulley 143 is fixed to the shaft 144 and pivots about a pivot axis Ax2 substantially parallel to the pivot axis Ax1. The shaft 144 is provided with a male screw of a feed screw mechanism. Due to the

pivoting of the shaft 144, a slider (not illustrated) of the feed screw mechanism linearly moves, and accordingly, the transfer unit 131 linearly moves. That is, in the present embodiment, the rotation of the shaft 132a of the motor 132 is transmitted to the slider via the power transmission mechanism 140 and is converted into the linear movement of the slider, and the transfer unit 131 linearly moves, namely, operates as the slider linearly moves. In the present embodiment, the power transmission mechanism 140 may also be referred to as a motion conversion mechanism or a rotation-to-linear motion conversion mechanism. In this structure, the pulleys 141 and 143, the belt 142, and the shaft 144 are examples of operating parts that operate in conjunction with the shaft 132a. Note that the output unit and the power transmission mechanism are not limited to the structure of the present embodiment. The drive unit may be, for example, another motor such as an air motor, or may have an output unit that linearly reciprocates, such as a linear actuator. The power transmission mechanism may have another structure that converts pivoting or linear movement of the output unit into swing or linear movement of an operating unit. The operating parts may also be other parts such as a chain, a gear, or a cam.

As in the present embodiment, in the power transmission mechanism 140, in a case where operating parts are interlocked with each other by frictional force, are brought into contact with and separated from each other, or are engaged with each other, or an operating part and a support part supporting the operating part slide, dust may be generated due to wear or the like. According to the study of the inventors, it has been found that in the structure of the present embodiment, a portion where the belt 142 is wound around the pulleys 141 and 143 is more likely to generate dust than other portions do. When the dust adheres to the storage container 20 or an article stored in the storage container 20, there is a possibility that the dust adversely affects the quality of the article such as deterioration.

Therefore, in the present embodiment, as is clear from comparison between FIGS. 3 and 4, the transfer mechanism 130 is provided with the cover 140a that covers the portion where dust may be generated. The cover 140a covers a portion where dust may be generated between the cover and the wall 133a, that is, the portion where the belt 142 is wound around the pulleys 141 and 143.

However, in a case where the portion where the wall 133a and the cover 140a may generate dust is sealed, dust may accumulate in the sealed space. In this case, there is a possibility that the accumulated dust increases the resistance when operating parts in the cover 140a operate. In addition, it may take time and effort to remove dust accumulated during maintenance performed by removing the cover 140a.

Therefore, in the present embodiment, as illustrated in FIG. 4, the wall 133a includes openings 133b and 133c that penetrate the wall 133ain the up-down direction and communicate the inside and the outside of the space between the wall 133a and the cover 140a (hereinafter, also simply referred to as the space). According to this structure, since dust can be discharged downward through the openings 133b and 133c, accumulation of dust between the wall 133a and the cover 140a can be suppressed. As a result, it is possible to suppress the occurrence of inconvenient events as described above due to the accumulated dust.

The opening 133b is formed immediately below the winding portion of the belt 142 around the pulley 143. Therefore, dust generated by friction between the pulley 143 and the belt 142 can be more reliably discharged by the opening 133b.

The opening 133c is a through hole through which a screw 135 (bolt) for fixing the bracket 140b for attaching the motor 132 to the wall 133a passes. The opening 133cis a long hole extending in the Y direction such that the position of the bracket 140b in the Y direction can be adjusted in order to set an appropriate tension of the belt 142. The Y direction is a direction in which the pivot axes Ax1 and Ax2 substantially parallel to each other of the two pulleys 141 and 143 are arranged. That is, in the present embodiment, the opening 133c, which is a hole for fixing the screw 135, is used as an opening for discharging dust. As a result, it is possible to reduce labor and cost required for processing the openings as compared with a case where the opening for fixing the screw 135 and the opening for discharging dust are separately formed. Furthermore, in this structure, since the opening 133c is a long hole, there is also an advantage that the opening is easily exposed from a bottom plate portion of the bracket 140b that is overlapping the wall 133a. The position of the bracket 140bin the Y direction, namely, the positions of the pulley 141 and the pivot axis Ax1 can be modified (adjusted) by an adjustment screw 137 capable of modifying the relative position with respect to the wall 133a in the Y direction.

In addition, one of the plurality of openings 133b and 133c formed in the wall 133a may be an intake port for the space between the wall 133a and the cover 140a, and the other may be an exhaust port due to a pressure difference between the openings 133b and 133c. In this case, an airflow flowing from the outside to the outside via the intake port, the space, and the exhaust port is easily formed, whereby the dust is more easily carried by the airflow to be discharged. The openings 133band 133care an example of first openings.

As described above, in the present embodiment, the downward airflow delivered from the blower 400 hits the transfer machine 100. Therefore, in a vertically extending space (conveyance passage) where the transfer machine 100 and the conveyance device 10 are positioned, the dust discharged from the opening 133b can be carried downward by the downward airflow. Accordingly, it is possible to prevent dust from reaching and affecting a storage container 20 positioned in the storage shelf 300.

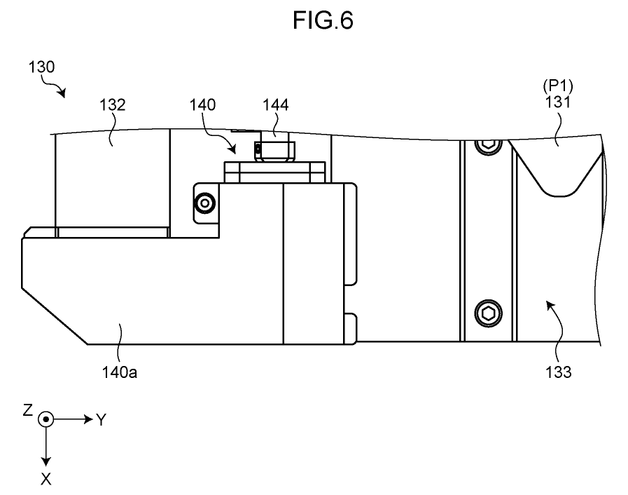

FIG. 6 is a plan view of a part of the transfer mechanism 130. As illustrated in FIG. 6, the cover 140a and the transfer unit 131 positioned at the retracting position P1 do not overlap each other in the Z direction, that is, the up-down direction. If the cover 140aand the transfer unit 131 positioned at the retracting position P1 overlap each other in the up-down direction, there is a risk that the dust may be hindered from being carried downward by the airflow. For example, in a case where the transfer unit 131 is present in such a manner as to overlap an upper side of the cover 140a, the transfer unit 131 may make the airflow less likely to reach the periphery of the cover 140a. In addition, there is a possibility that the airflow containing dust is disturbed and that the dust reaches a storage container 20 positioned in the storage shelf 300. In this regard, in the present embodiment, since the cover 140a and the transfer unit 131 positioned at the retracting position P1 do not overlap each other in the up-down direction, such an inconvenient event is unlikely to occur.

In addition, as illustrated in FIG. 2, openings 114a may be formed in the top plate 114 to suppress the top plate 114 from interfering with the flow of the airflow toward the cover 140a.

### Modification (1)

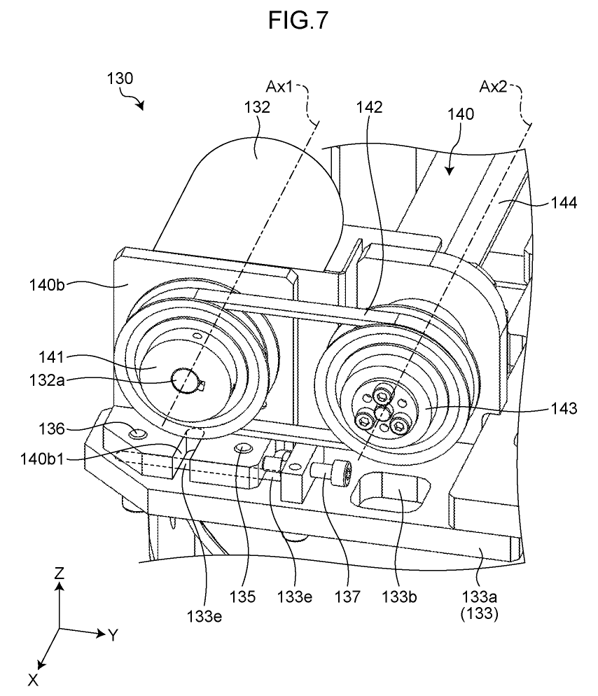

FIG. 7 is a perspective view in a state where a part of a cover 140a of a transfer mechanism 130 is removed, the transfer mechanism 130 having a modification of an opening 133e formed in a wall 133a and a modification of a bracket 140b. As illustrated in FIG. 7, in this modification, the wall 133a includes the long hole-shaped opening 133e that is longer in the Y direction and has a shape in which the two openings 133c and 133d illustrated in FIG. 5 are integrated. Furthermore, a cutaway opening 140b1 is formed in a bottom plate portion of the bracket 140b overlapping the wall 133a. A space between the wall 133aand the cover 140a is opened downward through a portion of the opening 133e overlapping the opening 140b1. In this structure, the portion of the opening 133e overlapping the opening 140b1 is formed immediately below a winding portion of a belt 142 around a pulley 141. Therefore, the dust generated by the friction between the pulley 141 and the belt 142 can be more reliably discharged by this portion. Furthermore, the space between the wall 133aand the cover 140a is opened downward via a total of three places including two places of the opening 133e not covered by the bracket 140b and an opening 133b. Therefore, an airflow is likely to be generated in the space, whereby accumulation of dust in the space is more easily suppressed.

### Modification (2)

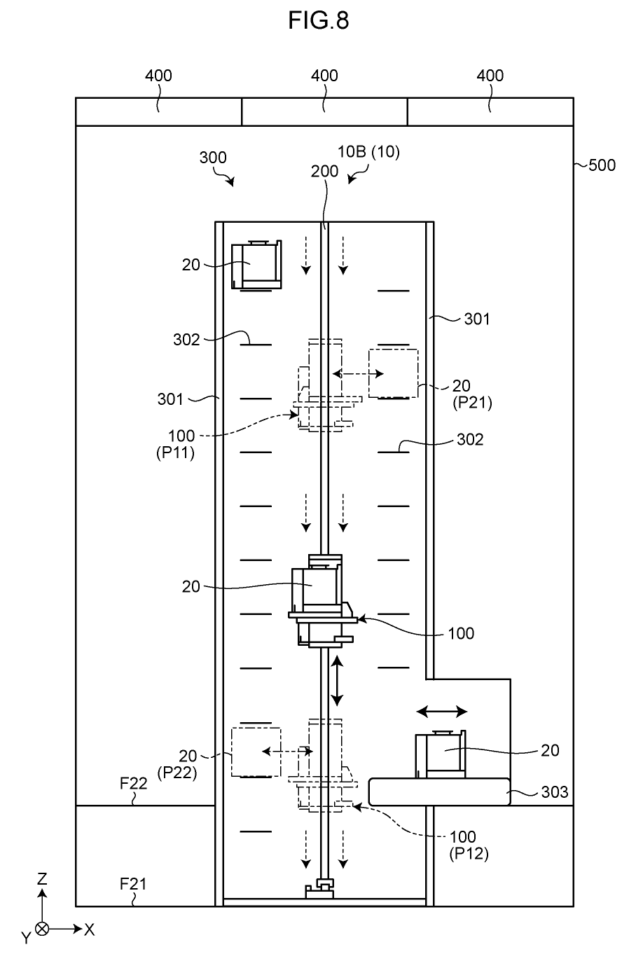

FIG. 8 is a side view of a conveyance device 10B (10) and a storage shelf 300 provided with a modification of a blower 400. As illustrated in FIG. 8, blowers 400 may be provided on the ceiling of a building 500 that houses the storage shelf 300. In addition, the building 500 may be provided with an upper (middle) floor F22 (grating) such as a grating, and the storage shelf 300 and the conveyance device 10 may be installed on a lower floor F21. In this structure, a downward airflow delivered from the blower 400 can be more efficiently discharged from between the floors F21 and F22. Note that the storage shelf 300 and the conveyance device 10 may be installed on a floor F22 in a building 500 in which floors F21 and F22 similar to those of FIG. 8 are installed.

As described above, in the present embodiment, the dust generating portion of the power transmission mechanism 140 is covered with the wall 133a provided on the second base 133 of the transfer machine 100 and the cover 140a covering the wall 133a. In this structure, openings 133b, 133c, and 133e penetrating the wall 133ain the up-down direction are formed. According to this structure, the dust generated at the dust generating portion is discharged (downward) to the outside of the space through the openings 133b, 133c, and 133e, whereby it is possible to suppress the dust from accumulating in the space. Therefore, it is possible to suppress the occurrence of inconveniences such as an increase in resistance when an operating part in the space is operated due to the accumulated dust, and requiring time and effort for removing the accumulated dust in maintenance performed by removing the cover 140a.

In the present embodiment, the wall 133a includes a plurality of openings 133b, 133c, and 133e (first openings) that communicate the inside and the outside of the space. According to this structure, the airflow flowing into the space and flowing out to the outside of the space via the space is easily generated by the plurality of openings 133b, 133c, and 133e, whereby the dust is easily discharged.

In the present embodiment, the openings 133c and 133e are long holes through which screws 135 and 136 for fixing operating parts such as the motor 132 or the pulley 141 pass. According to this structure, it is possible to reduce labor and cost for manufacturing the transfer machine 100 as compared with a case where the openings 133c and 133e are formed separately from a long hole for fixing.

In the present embodiment, the cover 140a does not overlap the transfer unit 131 positioned at a retracting position P1 in the Z direction. According to this structure, it is possible to suppress the transfer unit 131 from hindering carriage of the dust by a downward airflow generated in the vicinity of the cover 140a.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A transfer machine comprising:
a base having a wall intersecting an up-down direction;
a transfer unit movably provided on the base, the transfer unit being configured to support and transfer an article;
a drive unit provided on the base and having an output unit;
a power transmission mechanism provided on the base and having a plurality of operating parts, the power transmission mechanism being configured to transmit an operation of the output unit to the transfer unit to operate the transfer unit; and
a cover provided on the base and covering a portion of the power transmission mechanism that generates dust by the operation of the operating parts between the cover and the wall, wherein
an opening penetrating the wall in the up-down direction is formed in a portion of the wall covered by the cover.

2. The transfer machine according to claim 1, wherein
a downward airflow strikes the transfer machine,
the transfer unit moves between a protruding position protruding from the base and a retracting position having a smaller protruding amount from the base than a protruding amount at the protruding position, and
the cover does not overlap the transfer unit at the retracting position in the up-down direction.

3. The transfer machine according to claim 1, wherein a plurality of first openings are formed as the opening.

4. The transfer machine according to claim 1, wherein the opening is a long hole through which a screw for fixing the drive unit or the operating parts passes.

5. The transfer machine according to claim 2, wherein the opening is a long hole through which a screw for fixing the drive unit or the operating parts passes.

6. The transfer machine according to claim 3, wherein the opening is a long hole through which a screw for fixing the drive unit or the operating parts passes.
